(19) United States
(12) Patent Application Publication
(10) Pub. No.: US 2026/0162709 A1
(43) Pub. Date: Jun. 11, 2026

(54) STACKED MEMORY WORDLINE OFF BIAS CONTROL

(71) Applicant: Samsung Electronics Co., Ltd., Suwon-si (KR)

(72) Inventors: Hyunsu YOON, San Jose, CA (US); Jongsik NA, Dublin, CA (US)

(21) Appl. No.: 19/245,253

(22) Filed: Jun. 20, 2025

Related U.S. Application Data
(60) Provisional application No. 63/729,285, filed on Dec. 6, 2024.

(51) Int. Cl. G11C 11/408; G11C 11/4074; G11C 11/4093

(52) U.S. Cl. CPC G11C 11/4085; G11C 11/4074; G11C 11/4093

(57) ABSTRACT

Provided are systems, methods, and apparatuses for stacked memory wordline off bias control. In one or more examples, the systems, devices, and methods include applying a first negative bias voltage to a wordline circuit of a stacked memory module, the wordline circuit being associated with a first set of wordlines of the stacked memory module; determining a wordline of the first set of wordlines is activated; applying a second negative bias voltage to the wordline circuit instead of the first negative bias voltage based on the wordline being activated; determining the wordline is deactivated; and re-applying the first negative bias voltage to the wordline circuit based on the wordline being deactivated.

### CROSS-REFERENCE TO RELATED APPLICATIONS

This application claims the benefit of U.S. Provisional Patent Application Ser. No. 63/729,285, filed Dec. 6, 2024, which is incorporated by reference herein for all purposes.

### TECHNICAL FIELD

The disclosure relates generally to memory systems. In particular, the subject matter relates to stacked memory wordline off bias control.

### BACKGROUND

The present background section is intended to provide context only, and the disclosure of any concept in this section does not constitute an admission that said concept is prior art.

Memory chips can include integrated circuits that store and retrieve data in digital devices, such as computers, mobile devices, etc. Memory chips can store data temporarily or permanently. Memory chips can include random-access memory (RAM), dynamic random-access memory (DRAM), read-only memory (ROM), flash memory, etc. Memory chips can include output lines that connect to a system data bus. A decoder can select a single memory chip for the microprocessor to access. Some memory chips may be cut from a wafer and placed in individual housings. Memory chips can be mounted to a printed circuit board (PCB), incorporated on a system on chip (SoC), stacked vertically, etc.

### SUMMARY

In various embodiments, the systems and methods described herein include systems, methods, and apparatuses for stacked memory wordline off bias control. In various embodiments, the described technology provides a wordline circuit comprising three transistors. In some aspects, a first transistor is coupled to a first negative bias voltage and a first enable signal, while a second transistor is coupled to a second negative bias voltage and a second enable signal. In some embodiments, a third transistor is interconnected with the first two transistors, a wordline driving signal, and a wordline of the circuit. In some aspects, the drain of the second transistor connects to the source of the third transistor, and the drain of the first transistor connects similarly to the source of the third transistor, with the first and second enable signals, respectively, connected to the gates of the first and second transistors. In some aspects, additional embodiments include the third transistor having its drain connected to the wordline and its gate coupled to the wordline driving signal. In some embodiments, further variations incorporate a fourth transistor such that its drain connects to a second wordline driving signal, its gate is coupled to the first enable signal, and its source is connected to the wordline. In some embodiments, a fifth transistor may be included, with its drain coupled to the wordline and to the source terminal of the fourth transistor, its gate connected to both the first enable signal and the gate of the fourth transistor, and its source connected to the other transistors. In some aspects, the described technology relates to a wordline circuit wherein the second negative bias voltage is typically lower than the first negative bias voltage, with the first enable signal functioning as a complement to the second enable signal.

In various embodiments, the described technology further provides a method for operating a wordline circuit in a stacked memory module. In some aspects, the method comprises applying a first negative bias voltage to the circuit associated with a set of wordlines, and subsequently applying a second, lower negative bias voltage when a wordline is selected for activation. Accordingly, the method further comprises activating the selected wordline, re-applying the first negative bias voltage when the wordline is selected for deactivation, and then deactivating the wordline. In some aspects, the selection for activation is determined by raising an activation signal from a lower to a higher voltage level, whereas deactivation is determined by lowering the activation signal from the higher to the lower voltage level. In some embodiments, the activation signal may include a partial no write signal. In some aspects, in multi-circuit arrangements, a second wordline circuit may concurrently operate with the first circuit by applying the first negative bias voltage to one set of wordlines while the second negative bias voltage is applied to another set.

In various embodiments, the disclosed technology pertains to a stacked memory module comprising multiple wordline circuits, at least one of which includes the circuit features described herein. In some aspects, each wordline circuit within the module incorporates a first transistor coupled to a first negative bias voltage and a first enable signal, a second transistor coupled to a second negative bias voltage and a second enable signal, and a third transistor that connects the two transistors with a first wordline driving signal and a wordline. In some embodiments, various configurations extend the circuit to include additional transistors such as a fourth transistor connected to a second wordline driving signal and a fifth transistor interconnected with the other transistors, thereby enabling efficient management of wordline activation and deactivation across a plurality of stacked memory wordline circuits.

The systems and methods described herein provide deep wordline off voltage for an active MAT or wordline stack of a stacked memory module (e.g. 3D-DRAM, vertically stacked DRAM (VSDRAM)). The systems and methods described herein include multiple advantages and benefits. For example, the systems and methods provide low leakage to an un-selected DRAM cell. Additionally, the systems and methods provide low leakage to an un-selected DRAM cell. Low leakage in DRAM cells benefits memory retention time and reduces energy consumption, which can conserve battery power (e.g., in mobile devices). Low leakage also enhances the reliability of DRAM by minimizing the need for frequent refresh cycles, which can be a source of power waste and potential data loss.

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings, wherein:

FIG. 1 illustrates an example system in accordance with one or more implementations as described herein.

FIG. 2 illustrates an example circuit in accordance with one or more implementations as described herein.

FIG. 3 illustrates an example subarray in accordance with one or more implementations as described herein.

FIG. 4 illustrates an example circuit in accordance with one or more implementations as described herein.

FIG. 5 illustrates an example subarray in accordance with one or more implementations as described herein.

FIG. 6 illustrates an example system in accordance with one or more implementations as described herein.

FIG. 7 depicts a flow diagram illustrating an example method associated with the disclosed systems, in accordance with example implementations described herein.

FIG. 8 depicts a flow diagram illustrating an example method associated with the disclosed systems, in accordance with example implementations described herein.

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media includes all computer-readable media (including volatile and non-volatile media).

In one embodiment, a non-volatile computer-readable storage medium may include a floppy disk, flexible disk, hard disk, solid-state storage (SSS) (for example a solid-state drive (SSD)), solid state card (SSC), solid state module (SSM), enterprise flash drive, magnetic tape, or any other non-transitory magnetic medium, and/or the like. A non-volatile computer-readable storage medium may include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may include read-only memory (ROM), programmable read-only memory (PROM), erasable programmable read-only memory (EPROM), electrically erasable programmable read-only memory (EEPROM), flash memory (for example Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may include conductive-bridging random-access memory (CBRAM), phase-change random-access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random-access memory (FJG RAM), Millipede memory, racetrack memory, and/or the like.

In one embodiment, a volatile computer-readable storage medium may include random-access memory (RAM), dynamic random-access memory (DRAM), static random-access memory (SRAM), fast page mode dynamic random-access memory (FPM DRAM), extended data-out dynamic random-access memory (EDO DRAM), synchronous dynamic random-access memory (SDRAM), double data rate synchronous dynamic random-access memory (DDR SDRAM), double data rate type two synchronous dynamic random-access memory (DDR2 SDRAM), double data rate type three synchronous dynamic random-access memory (DDR3 SDRAM), Rambus dynamic random-access memory (RDRAM), Twin Transistor RAM (TTRAM), Thyristor RAM (T-RAM), Zero-capacitor (Z-RAM), Rambus in-line memory component (RIMM), dual in-line memory component (DIMM), single in-line memory component (SIMM), video random-access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of a hardware embodiment, a computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, a hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some examples, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms, and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms, and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some embodiments and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly referenced parts/modules are the only way to implement some of the embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on chip (SoC), an assembly, and so forth.

The provided description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications, will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification (e.g., any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

It is noted that, if used, the labels left, right, front, back, top, bottom, forward, reverse, clockwise and counterclockwise have been used for convenience purposes only and are not intended to imply any particular fixed direction. Instead, the labels are used to reflect relative locations and/or directions between various portions of an object.

Data processing may include data buffering, aligning incoming data from multiple communication lanes, forward error correction (FEC), etc. For example, data may be received by an analog front end (AFE), which can prepare the incoming data for digital processing. The digital portion of the transceivers (e.g., digital signal processor (DSP)) may provide skew management, equalization, reflection cancellation, and/or other functions. It is to be appreciated that the process described herein can provide many benefits, including saving both power and cost.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless explicitly stated otherwise, each numerical value and range may be interpreted as being approximate, as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations may be embodied in a single integrated circuit, a multi-chip module, a single card, SoC, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

As would be apparent to one skilled in the art, various functions of circuit elements may also be implemented as processing blocks in a software program. Such software may be employed in, for example, a digital signal processor, microcontroller, or general-purpose computer. Such software may be embodied in the form of program code embodied in tangible media, such as magnetic recording media, optical recording media, solid-state memory, floppy diskettes, CD-ROMs, hard drives, or any other non-transitory machine-readable storage medium, that when the program code is loaded into and executed by a machine, such as a computer, the machine becomes an apparatus for practicing the subject matter disclosed herein. When implemented on a general-purpose processor, the program code segments combine with the processor to provide a unique device that operates analogously to specific logic circuits. Described embodiments may also be manifest in the form of a bit stream or other sequence of signal values electrically or optically transmitted through a medium, stored magnetic-field variations in a magnetic recording medium, etc., generated using a method and/or an apparatus as described herein.

The systems and methods described herein may be based on and/or may include stacked memory modules (e.g., 3D DRAM, vertically stacked (VS) DRAM). Stacked memory may use 3D stacking technology to increase the memory cell density of memory chips. The stacked memory modules can provide higher bandwidth, faster data transfer, and lower power consumption, which can help extend battery life for some devices (e.g., mobile devices).

The systems and methods described herein may be based on and/or may include one or more wordline stacks. With stacked memory modules, a wordline stack may refer to an arrangement of wordlines (e.g., the wires that select rows of memory cells) in multiple layers stacked vertically. The wordline stack can enable the selection of memory cells in different layers and facilitate the scaling of DRAM capacity.

The systems and methods described herein may be based on and/or may include one or more memory array tiles (MATs). With stacked memory modules, a MAT can be a building block that organizes DRAM cells within a larger array. A MAT can include a sub-section of DRAM cells arranged in a grid structure of rows and columns (e.g., a number of wordlines and a number of bitlines). Wordline drivers can be used to select and activate a DRAM row within a MAT. MATs can reduce latency and improve memory density by organizing DRAM wordlines hierarchically. MATs can be grouped together to form subarrays, and multiple subarrays can make up a larger array of a stacked memory module. A MAT cell array may have its own dedicated wordline drivers and sense amplifiers for efficient data access. The systems and methods include circuit implementations for a “deep” VBB line that improves the electrical properties of a given MAT.

In some cases, a negative bias voltage (e.g., VBB) may be applied to the wordline of a DRAM when the wordline is off, which may be referred to as negative wordline bias. When the wordline is off (e.g., the cell is not actively being read or written to), applying a negative bias to the cell can help reduce the leakage current through the cell transistor. Negative wordline bias can be used to reduce standby current and improve data retention. The negative wordline bias can also enhance data retention by reducing gate-induced drain leakage (GIDL), a type of leakage current that contributes to data loss in DRAM. Negative wordline bias may be based on leveraging the subthreshold current of an NMOS transistor in the sub-wordline driver (SWD) circuit. The negative bias applied to the wordline can create a depletion region in the drain of the NMOS transistor, reducing the subthreshold current and the amount of current leakage. Thus, when the wordline is off, a negative bias may be applied to the source of the NMOS transistor, which in turn increases the transistor's subthreshold current and effectively reduces the standby current.

Deep negative bias (e.g., a secondary negative bias that is a lower voltage than a default negative bias) may provide benefits for DRAM cells (e.g., further reduce current leakage). However, because of GIDL, it can be difficult to implement deep negative bias (e.g., implement all the time). The systems and methods described herein provide deep negative bias that is assigned (e.g., only assigned) to an activated area. The systems and methods may be based on systems with active MAT (e.g., active MAT only) and/or active WL stack on VSDRAM. To prevent off current, negative back-bias voltage (e.g., VBB2) may be used for wordline off bias.

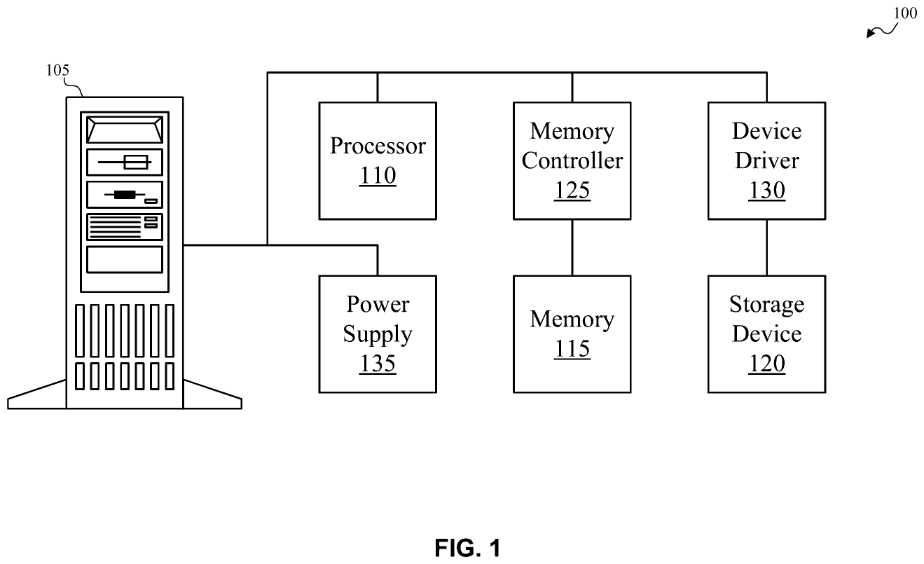

FIG. 1 illustrates an example system 100 in accordance with one or more implementations as described herein. In FIG. 1, machine 105, which may be termed a host, a system, or a server, is shown. While FIG. 1 depicts machine 105 as a tower computer, embodiments of the disclosure may extend to any form factor or type of machine. For example, machine 105 may be a rack server, a blade server, a desktop computer, a tower computer, a mini tower computer, a desktop server, a laptop computer, a notebook computer, a tablet computer, etc.

Machine 105 may include processor 110, memory 115, and storage device 120. Processor 110 may be any variety of processor. It is noted that processor 110, along with the other components discussed below, are shown outside the machine for ease of illustration: embodiments of the disclosure may include these components within the machine. While FIG. 1 shows a single processor 110, machine 105 may include any number of processors, each of which may be single core or multi-core processors, each of which may implement a Reduced Instruction Set Computer (RISC) architecture or a Complex Instruction Set Computer (CISC) architecture (among other possibilities), and may be mixed in any desired combination.

Processor 110 may be coupled to memory 115. Memory 115 may be any variety of memory, such as flash memory, DRAM, SRAM, Persistent Random-access memory, Ferroelectric Random-access memory (FRAM), or Non-Volatile Random-access memory (NVRAM), such as Magnetoresistive Random-access memory (MRAM), Phase Change Memory (PCM), or Resistive Random-Access Memory (ReRAM). In some cases, at least a portion of memory 115 may include stacked memory (e.g., 3D DRAM, VSDRAM). Memory 115 may include volatile and/or non-volatile memory. Memory 115 may use any desired form factor: for example, Single In-Line Memory Module (SIMM), Dual In-Line Memory Module (DIMM), Non-Volatile DIMM (NVDIMM), etc. Memory 115 may be any desired combination of different memory types, and may be managed by memory controller 125. Memory 115 may be used to store data that may be termed “short-term”: that is, data not expected to be stored for extended periods of time. Examples of short-term data may include temporary files, data being used locally by applications (which may have been copied from other storage locations), and the like.

Processor 110 and memory 115 may support an operating system under which various applications may be running. These applications may issue requests (which may be termed commands) to read data from or write data to either memory 115 or storage device 120. When storage device 120 is used to support applications reading or writing data via some sort of file system, storage device 120 may be accessed using device driver 130. While FIG. 1 shows one storage device 120, there may be any number (one or more) of storage devices in machine 105. Storage device 120 may support any desired protocol or protocols, including, for example, the Non-Volatile Memory Express (NVMe®) protocol, a Serial Attached Small Computer System Interface (SCSI) (SAS) protocol, or a Serial AT Attachment (SATA) protocol. Storage device 120 may include any desired interface, including, for example, a Peripheral Component Interconnect Express (PCIe®) interface, or a Compute Express Link (CXL®) interface. Storage device 120 may take any desired form factor, including, for example, a U.2 form factor, a U.3 form factor, a M.2 form factor, Enterprise and Data Center Standard Form Factor (EDSFF) (including all of its varieties, such as E1 short, E1 long, and the E3 varieties), or an Add-In Card (AIC).

While FIG. 1 uses the term “storage device,” embodiments of the disclosure may include any storage device formats that may benefit from the use of computational storage units, examples of which may include hard disk drives, solid state drives (SSDs), or persistent memory devices, such as PCM, ReRAM, or MRAM. Any reference to “storage device” “SSD” herein should be understood to include such other embodiments of the disclosure and other varieties of storage devices. In some cases, the term “storage unit” may encompass storage device 120 and memory 115. Machine 105 may include power supply 135. Power supply 135 may provide power to machine 105 and its components.

In one or more examples, machine 105 may be implemented with any type of apparatus. Machine 105 may be configured as (e.g., as a host of) one or more servers, such as a computation server, a storage server, storage node, a network server, a supercomputer, data center system, and/or the like, or any combination thereof. Additionally, or alternatively, machine 105 may be configured as (e.g., as a host of) one or more computers, such as a workstation, a personal computer, a tablet, a smartphone, and/or the like, or any combination thereof. Machine 105 may be implemented with any type of apparatus that may be configured as a device including, for example, an accelerator device, a storage device, a network device, a memory expansion and/or buffer device, a central processing unit (CPU), a graphics processing unit (GPU), a neural processing unit (NPU), a tensor processing unit (TPU), optical processing units (OPU), and/or the like, or any combination thereof.

Any communication between devices including machine 105 (e.g., host, computational storage device, and/or any intermediary device) can occur over an interface that may be implemented with any type of wired and/or wireless communication medium, interface, protocol, and/or the like including PCIe, NVMe, Ethernet, NVMe-oF, Compute Express Link (CXL), and/or a coherent protocol such as CXL.mem, CXL.cache, CXL.IO and/or the like, Gen-Z, Open Coherent Accelerator Processor Interface (OpenCAPI), Cache Coherent Interconnect for Accelerators (CCIX), Advanced eXtensible Interface (AXI) and/or the like, or any combination thereof, Transmission Control Protocol/Internet Protocol (TCP/IP), FibreChannel, InfiniBand, Serial AT Attachment (SATA), Small Computer Systems Interface (SCSI), Serial Attached SCSI (SAS), iWARP, any generation of wireless network including 2G, 3G, 4G, 5G, and/or the like, any generation of Wi-Fi, Bluetooth, near-field communication (NFC), and/or the like, or any combination thereof. In some embodiments, the communication interfaces may include a communication fabric including one or more links, buses, switches, hubs, nodes, routers, translators, repeaters, and/or the like. In some embodiments, system 100 may include one or more additional apparatus having one or more additional communication interfaces.

Any of the functionality described herein, including any of the host functionality, device functionally, and/or the like, may be implemented with hardware, software, firmware, or any combination thereof including, for example, hardware and/or software combinational logic, sequential logic, timers, counters, registers, state machines, volatile memories such as at least one of or any combination of the following: DRAM and/or SRAM, nonvolatile memory including flash memory, persistent memory such as cross-gridded nonvolatile memory, memory with bulk resistance change, PCM, and/or the like and/or any combination thereof, complex programmable logic devices (CPLDs), field programmable gate arrays (FPGAs), application specific integrated circuits (ASICs), CPUs including CISC processors such as x86 processors and/or RISC processors such as RISC-V and/or advanced RISC machine (ARM) processors, GPUs, NPUs, TPUs, OPUs, and/or the like, executing instructions stored in any type of memory.

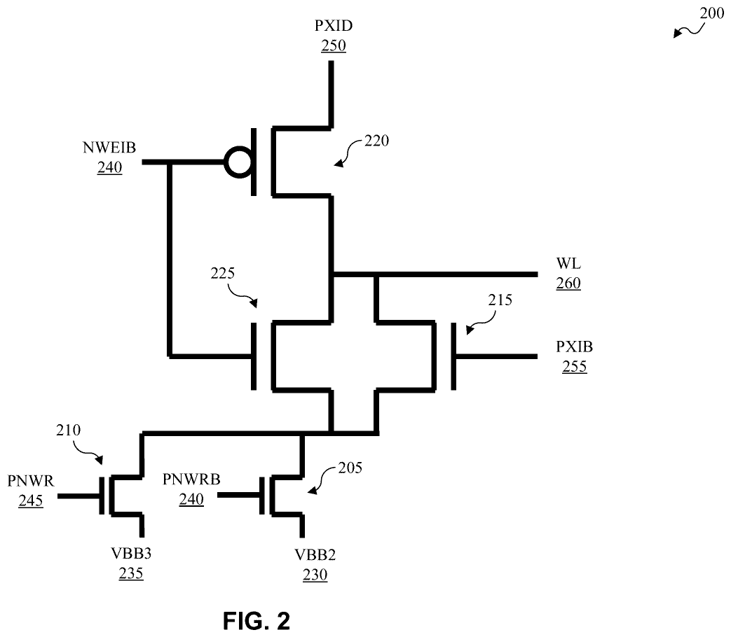

FIG. 2 illustrates an example circuit 200 in accordance with one or more implementations as described herein. In some configurations, one or more aspects of circuit 200 may be implemented by or in conjunction with machine 105, components of machine 105, or any combination thereof. In some cases, circuit 200 may depict aspects of a wordline circuit. Circuit 200 may be associated with at least one wordline. For example, circuit 200 may be associated with at least one wordline of a subsection or sub-array of a stacked memory module (e.g., of a MAT, of a wordline stack).

In the illustrated example, circuit 200 may include at least transistor 205, transistor 210, transistor 215, transistor 220, and transistor 225. As shown, circuit 200 may be associated with a variety of signals (e.g., DRAM control signals). These signals may include a first negative bias voltage (e.g., VBB2 230) and a second negative bias voltage (e.g., VBB3 235). In some cases, VBB2 230 may be based on a default negative bias voltage and VBB3 235 may be based on a deep negative bias voltage (e.g., a negative bias voltage that is lower than a default negative bias voltage).

As shown, the signals of circuit 200 may include partial no write (PNWR) enable signals (e.g., PNWRB 240 and PNWR 245) and wordline driving signals (e.g., PXID 250 and PXIB 255). PNWRB 240 and/or PNWR 245 may be activation signals (e.g., signals to activate switching from a default negative bias voltage to a deep negative bias voltage). In some cases, PNWRB 240 and/or PNWR 245 may indicate a wordline is selected for activation (e.g., switching PNWR 245 from a first voltage level to a second voltage level). PNWRB 240 may be the complement or inverse of PNWR 245. Sub-word line drivers (SWDs) may generate wordline enable signals PNWRB 240 and PNWR 245 for driving corresponding wordlines. PXID 250 may be the complement or inverse of PXIB 255. PXID 250 and PXIB 255 may be configured to drive the SWDs.

As shown, transistor 205 may be connected to the first negative bias voltage, VBB2 230, and the first wordline enable signal, PNWRB 240. Transistor 210 may be connected to a second negative bias voltage, VBB3 235, and the second wordline enable signal, PNWR 245. As shown, transistor 215 may be connected to transistor 205 and transistor 210, the first wordline driving signal, PXIB 255, and a wordline of circuit 200 (e.g., WL 260).

In the illustrated example, the drain terminal of transistor 205 and the drain terminal of transistor 210 may connect to a source terminal of transistor 215 (e.g., and connect to each other). The gate terminal of transistor 205 may connect to the first wordline enable signal PNWRB 240, and the gate terminal of transistor 210 may connect to the second wordline enable signal PNWR 245. As shown, the source terminal of transistor 205 may connect to the first negative bias voltage, VBB2 230, and the source terminal of transistor 210 may connect to the second negative bias voltage, VBB3 235.

In the illustrated example, the drain terminal of transistor 215 may connect to WL 260 and the gate terminal of transistor 215 may connect to the first wordline driving signal, PXIB 255 As shown, the drain terminal of transistor 220 may connect to the second wordline driving signal, PXID 250, the gate terminal of transistor 220 may connect to the first wordline enable signal, PNWRB 240, and the source terminal of transistor 220 may connect to a wordline of circuit 200, WL 260. In some examples, the second wordline driving signal, PXID 250, may be the complement of the first wordline driving signal, PXIB 255.

In the illustrated example, the drain terminal of transistor 225 may connect to a wordline of circuit 200, WL 260, and to the source terminal of transistor 220. The gate terminal of transistor 225 may connect to the first wordline enable signal, PNWRB 240, and to the gate terminal of transistor 220. The source terminal of transistor 225 may connect to the drain terminal of transistor 205, to the drain terminal of transistor 210, and to the source terminal of transistor 215 In some examples, the second negative bias voltage, VBB3 235, may be a lower voltage (e.g., more negative voltage) than the first negative bias voltage, VBB2 230. In some cases, the first wordline enable signal, PNWRB 240, may be the complement of the second wordline enable signal, PNWR 245.

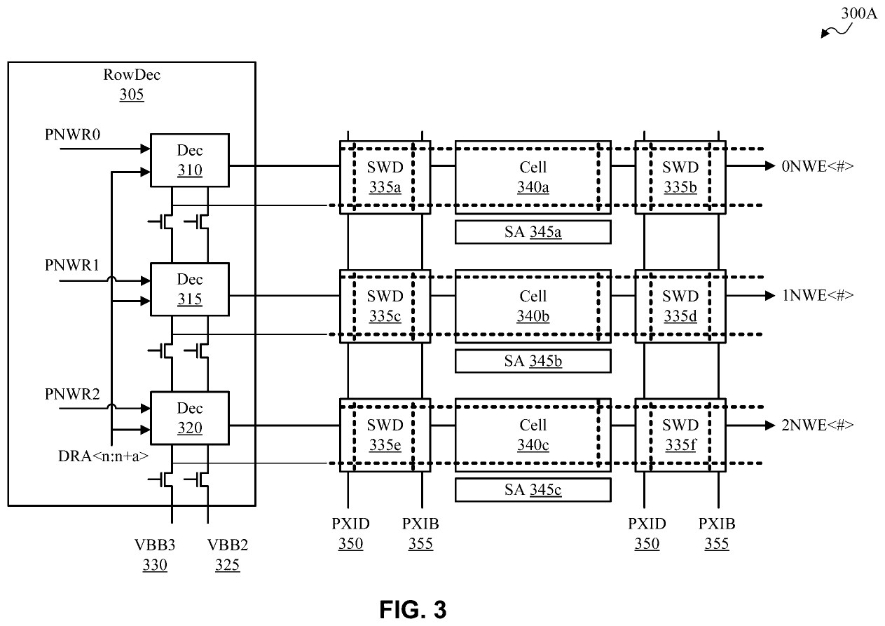

FIG. 3 illustrates an example subarray 300 in accordance with one or more implementations as described herein. In some configurations, one or more aspects of subarray 300 may be implemented by or in conjunction with machine 105, components of machine 105, or any combination thereof. In some cases, circuit 200 may be used in conjunction with subarray 300.

In the illustrated example, subarray 300 may include row decoder 305, which may include one or more decoders (e.g., decoder 310, decoder 315, decoder 320, etc.). In some examples, row decoder 305 may be associated with a MAT or wordline stack of a stacked memory module (e.g. 3D-DRAM, vertically stacked DRAM (VSDRAM)). For example, a stacked memory module may include an array of memory cells. In some cases, the stacked memory module may include a first layer with a first array of memory cells, a second layer with a second array of memory cells, and so on. A given array of a given layer of the stacked memory module may include one or more subarrays. Thus, subarray 300 may depict a subsection of an array (e.g., MAT or wordline stack) of a layer of the stacked memory module.

In some examples, row decoder 305 may be associated with a first subset of wordlines of the stacked memory module, a second row decoder may be associated with a second subset of wordlines of the stacked memory module, and so on. In some cases, row decoder 305 may be configured to select a row (e.g., wordline) within the memory array based on a row address. For example, decoder 310 may select a first wordline, decoder 315 may select a second wordline, decoder 320 may select a third wordline, etc. As shown, row decoder 305 may include an address signal for selecting a wordline (e.g., DRA<n:n+a>) where n may be some index value (e.g., 0, 1, 2, or some positive integer) and “a” may be some offset value (e.g., 6, 7, 8, or some positive integer). In some cases, DRA<n:n+a> may select a negative word line enable signal (e.g., NWEI, NWEIB) for activating a wordline (e.g., switch NWEI or NWEIB from a first voltage level to a second voltage level).

As shown, row decoder 305 may include a connection to a first negative bias voltage (e.g., VBB2 325) and a second negative bias voltage (e.g., VBB3 330). VBB2 325 may be a default negative bias voltage (e.g., VBB2 230) and VBB3 330 may be a deep negative bias voltage (e.g., VBB3 235). In some cases, VBB3 330 may be a more negative voltage than VBB2 325. In some cases, VBB2 325 and/or VBB3 330 may connect to the one or more decoders of row decoder 305 (e.g., decoder 310, decoder 315, decoder 320, etc.). In some cases, VBB2 325 and/or VBB3 330 may connect to a first wordline via decoder 310, to a second wordline via decoder 315, to a third wordline via decoder 320, etc. Thus, subarray 300 may depict controlling the switching of negative bias voltages via a row decoder (e.g., via row decoder 305).

Subarray 300 may include one or more sub-wordline drivers (SWDs), such as SWD 335a, SWD 335b, SWD 335c, SWD 335d, SWD 335e, SWD 335f, etc. Subarray 300 may include one or more memory cells (e.g., cell 340a, cell 340b, cell 340c), and one or more sense amplifiers (e.g., SA 345a, SA 345b, SA 345c, etc.). As shown, the one or more depicted SWDs may be driven by wordline driving signals (e.g., PXID 350 and PXIB 355). As shown, a voltage level from VBB2 325 or VBB3 330 may be provided to the SWDs 335 and/or Cells 340 via row decoder 305.

In subarray 300, one wordline may be activated at a given time. For example, when decoder 310 activates a wordline, a wordline of decoder 315 and a wordline of decoder 320 may be inactive or deactivated. When no wordline of subarray 300 is activated, the negative bias voltage of subarray 300 may be based on a default negative bias voltage (e.g., VBB2 325). When a wordline of subarray 300 is activated, then the negative bias voltage of subarray 300 may be switched via row decoder 505 from a default negative bias voltage (e.g., VBB2 325) to a deep negative bias voltage (e.g., VBB3 330). In some cases, the deep negative bias may be applied to the active wordline of subarray 300. Additionally, or alternatively, the deep negative bias may be applied to one or more inactive wordlines of subarray 300. When the active wordline of subarray 300 is deactivated, then the negative bias voltage of subarray 300 may be switched from the deep negative bias voltage (e.g., VBB3 330) to the default negative bias voltage (e.g., VBB2 325).

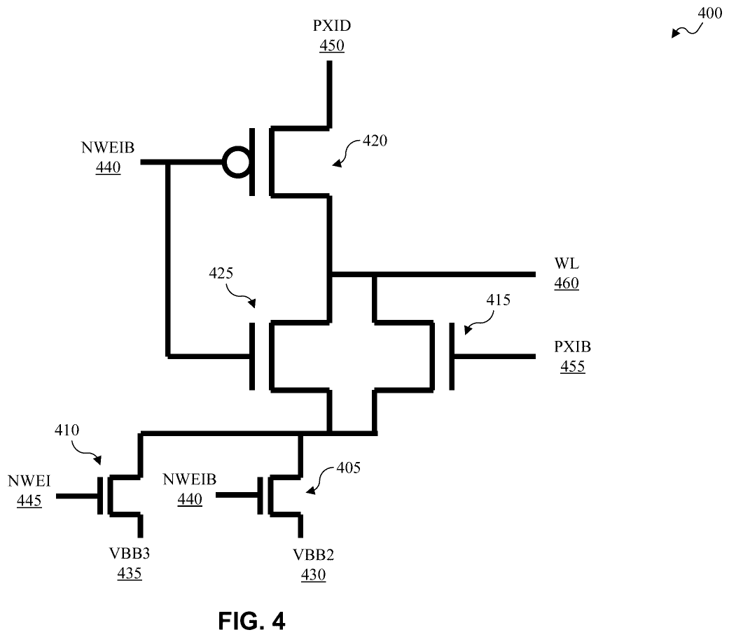

FIG. 4 illustrates an example circuit 400 in accordance with one or more implementations as described herein. In some configurations, one or more aspects of circuit 400 may be implemented by or in conjunction with machine 105, components of machine 105, or any combination thereof. In some cases, circuit 400 may depict aspects of a wordline circuit. Circuit 400 may be associated with at least one wordline. For example, circuit 400 may be associated with at least one wordline of a subsection or sub-array of a stacked memory module (e.g., of a MAT, of a wordline stack).

In the illustrated example, circuit 400 may include at least transistor 405, transistor 410, transistor 415, transistor 420, and transistor 425. As shown, circuit 400 may be associated with a variety of signals (e.g., DRAM control signals). These signals may include a first negative bias voltage (e.g., VBB2 430) and a second negative bias voltage (e.g., VBB3 435). In some cases, VBB2 430 may be based on a default negative bias voltage and VBB3 435 may be based on a deep negative bias voltage (e.g., a negative bias voltage that is lower than a default negative bias voltage).

As shown, the signals of circuit 400 may include negative word line enable signals (e.g., NWEIB 440 and NWEI 445) and wordline driving signals (e.g., PXID 450 and PXIB 455). As shown, NWEIB 440 and NWEI 445 may be configured as enable signals for switching between a first negative bias voltage and a second negative bias voltage. NWEIB 440 may be the complement or inverse of NWEI 445. Sub-word line drivers (SWDs) may generate wordline enable signals NWEIB 440 and NWEI 445 for driving corresponding wordlines. PXID 450 may be the complement or inverse of PXIB 455. PXID 450 and PXIB 455 may be configured to drive the SWDs.

As shown, transistor 405 may be connected to the first negative bias voltage, VBB2 430, and the first wordline enable signal, NWEIB 440. Transistor 410 may be connected to a second negative bias voltage, VBB3 435, and the second wordline enable signal, NWEI 445. As shown, transistor 415 may be connected to transistor 405 and transistor 410, the first wordline driving signal, PXIB 455, and a wordline of circuit 400 (e.g., WL 460).

In the illustrated example, the drain terminal of transistor 405 and the drain terminal of transistor 410 may connect to a source terminal of transistor 415 (e.g., and connect to each other). The gate terminal of transistor 405 may connect to the first wordline enable signal NWEIB 440, and the gate terminal of transistor 410 may connect to the second wordline enable signal NWEI 445. As shown, the source terminal of transistor 405 may connect to the first negative bias voltage, VBB2 430, and the source terminal of transistor 410 may connect to the second negative bias voltage, VBB3 435.

In the illustrated example, the drain terminal of transistor 415 may connect to WL 460 and the gate terminal of transistor 415 may connect to the first wordline driving signal, PXIB 455 As shown, the drain terminal of transistor 420 may connect to the second wordline driving signal, PXID 450, the gate terminal of transistor 420 may connect to the first wordline enable signal, NWEIB 440, and the source terminal of transistor 420 may connect to a wordline of circuit 400, WL 460. In some examples, the second wordline driving signal, PXID 450, may be the complement of the first wordline driving signal, PXIB 455.

In the illustrated example, the drain terminal of transistor 425 may connect to a wordline of circuit 400, WL 460, and to the source terminal of transistor 420. The gate terminal of transistor 425 may connect to the first wordline enable signal, NWEIB 440, and to the gate terminal of transistor 420. The source terminal of transistor 425 may connect to the drain terminal of transistor 405, to the drain terminal of transistor 410, and to the source terminal of transistor 415. In some examples, the second negative bias voltage, VBB3 435, may be a lower voltage (e.g., more negative voltage) than the first negative bias voltage, VBB2 430. In some cases, the first wordline enable signal, NWEIB 440, may be the complement of the second wordline enable signal, NWEI 445.

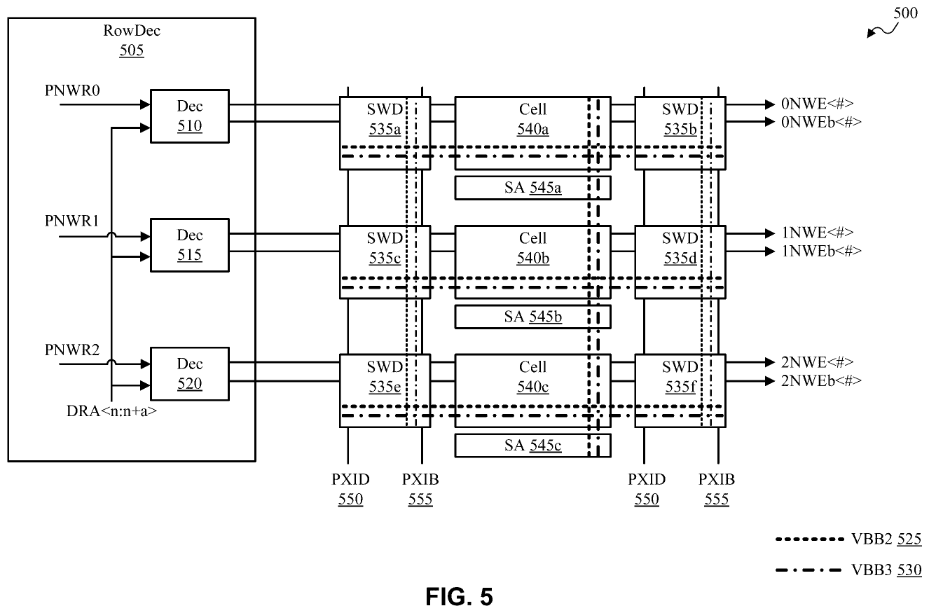

FIG. 5 illustrates an example subarray 500 in accordance with one or more implementations as described herein. In some configurations, one or more aspects of subarray 500 may be implemented by or in conjunction with machine 105, components of machine 105, or any combination thereof.

In the illustrated example, subarray 500 may include row decoder 505, which may include one or more decoders (e.g., decoder 510, decoder 515, decoder 520, etc.). In some examples, row decoder 505 may be associated with a MAT or wordline stack of a stacked memory module (e.g. 3D-DRAM, vertically stacked DRAM (VSDRAM)). For example, a stacked memory module may include an array of memory cells. In some cases, the stacked memory module may include a first layer with a first array of memory cells, a second layer with a second array of memory cells, and so on. A given array of a given layer of the stacked memory module may include one or more subarrays. Thus, subarray 500 may depict a subsection of an array (e.g., MAT or wordline stack) of a layer of the stacked memory module.

In some examples, row decoder 505 may be associated with a first subset of wordlines of the stacked memory module, a second row decoder may be associated with a second subset of wordlines of the stacked memory module, and so on. In some cases, row decoder 505 may be configured to select a row (e.g., wordline) within the memory array based on a row address. For example, decoder 510 may select a first wordline, decoder 515 may select a second wordline, decoder 520 may select a third wordline, etc.

In some cases, subarray 500 may be implemented in conjunction with circuit 400. For example, circuit 400 may provide a first negative bias voltage (e.g., VBB2 430) and a second negative bias voltage (e.g., VBB3 435) to subarray 500. As shown, row decoder 505 may include connections to VBB2 525 and VBB3 530. VBB2 525 may be an example of VBB2 430 and VBB3 530 may be an example of VBB3 435. VBB2 525 may be a default negative bias voltage and VBB3 530 may be a deep negative bias voltage. In some cases, VBB3 530 may be a more negative voltage than VBB2 525.

Subarray 500 may include one or more sub-wordline drivers (SWDs), such as SWD 535a, SWD 535b, SWD 535c, SWD 535d, SWD 535e, SWD 535f, etc. Subarray 500 may include one or more memory cells (e.g., cell 540a, cell 540b, cell 540c), and one or more sense amplifiers (e.g., SA 545a, SA 545b, SA 545c, etc.). As shown, the one or more depicted SWDs may be driven by wordline driving signals (e.g., PXID 550 and PXIB 555). As shown, VBB2 525 and/or VBB3 530 may connect to the one or more SWDs 535 and/or cells 540 of subarray 500. In some cases, VBB2 525 and/or VBB3 530 may connect to a first wordline via a first SWD and/or first cell, to a second wordline via a second SWD and/or second cell, to a third wordline via a third SWD and/or third cell, etc. Thus, subarray 500 may depict controlling the switching of negative bias voltages via the SWDs and/or cells of subarray 500.

In subarray 500, one wordline may be activated at a given time. For example, when decoder 510 activates a wordline, a wordline of decoder 515 and a wordline of decoder 520 may be inactive or deactivated. When no wordline of subarray 500 is activated, the negative bias voltage of subarray 500 may be based on a default negative bias voltage (e.g., VBB2 525). When a wordline of subarray 500 is activated, then the negative bias voltage of subarray 500 may be switched from a default negative bias voltage (e.g., VBB2 525) to a deep negative bias voltage (e.g., VBB3 530). In some cases, the deep negative bias may be applied to the active wordline of subarray 500. Additionally, or alternatively, the deep negative bias may be applied to one or more inactive wordlines of subarray 500. When the active wordline of subarray 500 is deactivated, then the negative bias voltage of subarray 500 may be switched from the deep negative bias voltage (e.g., VBB3 530) to the default negative bias voltage (e.g., VBB2 525).

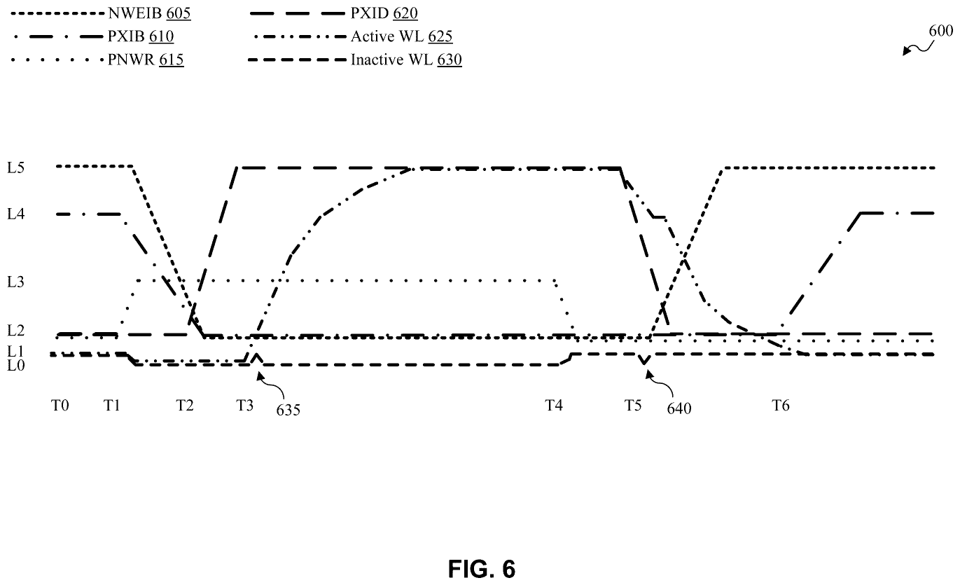

FIG. 6 illustrates an example graph 600 in accordance with one or more implementations as described herein. As shown, graph 600 may depict a signal graph or a graph of signals relative to time. In some configurations, one or more aspects of graph 600 may be implemented by or in conjunction with machine 105, components of machine 105, or any combination thereof.

In the illustrated example, graph 600 may depict voltage levels (e.g., L0, L1, L2, L3, L4, L5) of various signals associated with a stacked memory module (e.g., signals of a MAT, DRAM control signals). As shown, graph 600 depicts the various signals relative to one or more points of time (e.g., T0, T1, T2, T3, T4, T5, T6).

The various signals of graph 600 may include NWEIB 605, PXIB 610, PNWR 615, PXID 620, active WL 625, and inactive WL 630. Active WL 625, and inactive WL 630 may be wordlines of a given MAT or wordline stack. Inactive WL 630 may represent one or more inactive WLs of the MAT or wordline stack.

At or relatively near T0, NWEIB 605 may be at L5, PXIB 610 may be at L4, PNWR 615 and PXID may be at L2, and active WL 625 and inactive WL 630 may be at L1. In some cases, L1 may represent the level of a first negative bias voltage (e.g., default negative bias voltage), and L0 may represent a level of a second negative bias voltage (e.g., deep negative bias voltage).

At or relatively near T1, NWEIB 605 may be lowered from L5 to L2, PXIB 610 may be lowered from L4 to L2, and/or PNWR 615 may be raised from L2 to L3. In some cases, lowering NWEIB 605, lowering PXIB 610, and/or raising PNWR 615 may indicate activation of active WL 625 (e.g., activation signal). As shown, at or relatively near T1, a second negative bias (e.g., deep negative bias at L0) may be applied to at least inactive WL 630. In the illustrated example, the second negative bias may be applied to active WL 625 and inactive WL 630, lowering active WL 625 and inactive WL 630 from L1 to L0 (e.g., from a default negative bias voltage to a deep negative bias voltage). In some cases, the second negative bias may be applied to active WL 625 and inactive WL 630 based on lowering NWEIB 605, lowering PXIB 610, and/or raising PNWR 615. For example, PNWR 615 may be an activation signal for switching from a default negative bias to a deep negative bias.

It is noted that active WL 625 and inactive WL 630 may be from a first set of wordlines (e.g., of a given MAT or wordline stack). A memory device that includes this first set of wordlines may include at least a second set of wordlines different from the first set of wordlines. In some cases, the first negative bias voltage may be applied to at least the second set of wordlines concurrent with the second negative bias voltage being applied to active WL 625 and/or inactive WL 630 (e.g., applied to the first set of wordlines). For example, for at least a portion of the time period that the second negative bias voltage is applied to active WL 625 and/or inactive WL 630, the first negative bias voltage may be applied to at least one wordline of at least one other set of wordlines of the memory device (e.g., at least the second set of wordlines).

At or relatively near T2, PXID 620 may be raised from L2 to L5. At or relatively near T3, active WL 625 may be raised from L0 to L5. As shown, at or relatively near T3, a blip 635 may occur on inactive WL 630 (e.g., an upward blip, or blip in a positive voltage direction). In some cases, blip 635 may be caused by coupling between active WL 625 and inactive WL 630 based on the activation of active WL 625.

In some cases, blip 635 can cause additional leakage in an unselected wordline (e.g., inactive WL 630) For example, a first wordline may be adjacent to a second wordline. The first wordline may be in an inactive or unselected state. The second wordline may be activated. When the second wordline is activated, the voltage applied to the second wordline may be coupled to the first wordline, causing a blip in the first wordline. The blip can cause an NMOS of the first wordline to turn on to some degree (e.g., turn on slightly), which can result in leakage or a higher level of leakage on the first wordline. This leakage can result in data loss. Leakage in DRAM memory (e.g., gate-induced drain leakage (GIDL)), can cause a loss of stored charge, leading to data degradation or data loss. In some cases, higher rates of leakage can result in higher rates of refresh cycles, which can increase power consumption, making the DRAM memory less efficient. Accordingly, lowering the rate of leakage can reduce power consumption and reduce the risk of data degradation and data loss, improving the efficiency and reliability of memory systems.

As shown, if the negative bias is not lowered from L1 to L0, then the effect of blip 635 is more pronounced (e.g., more leakage), because the blip exceeds the default level of negative bias. But when negative bias is lowered below the default level (e.g., from L1 to L0), then the effect of blip 635 only comes up to the default level of negative bias at L1, which prevents the blip 635 from increasing leakage. However, applying a more negative bias at all times can increase leakage (e.g., increase GIDL) over time. Accordingly, deep negative bias L0 may be applied to a subsection of the DRAM when (e.g., only when) an active WL period, and then returned to the default negative bias.

At or relatively near T4, PNWR 615 may be lowered from L3 to L2. In some cases, lowering PNWR 615 may indicate deactivation of active WL 625. As shown, at or relatively near T4, inactive WL 630 may be raised from L0 to L1 (e.g., from a deep negative bias to a default negative bias). For example, the negative bias may be switched from the deep negative bias back to the default negative bias.

At or relatively near T5, PXID 620 may be lowered from L5 to L2. As shown, at or relatively near T5, a blip 640 may occur on inactive WL 630 (e.g., a downward or negative blip). In some cases, blip 640 may be caused by coupling between active WL 625 and inactive WL 630 based on the deactivation of active WL 625. At or relatively near T6, PXIB 610 may be raised from L2 to L4.

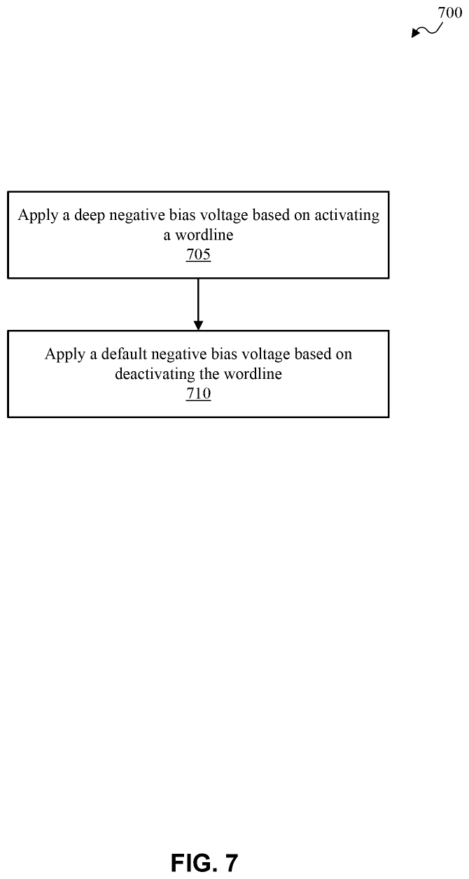

FIG. 7 depicts a flow diagram illustrating an example method 700 associated with the disclosed systems, in accordance with example implementations described herein. In some configurations, one or more aspects of method 700 may be implemented by or in conjunction with machine 105, components of machine 105, or any combination thereof. The depicted method 700 is just one implementation and one or more operations of method 700 may be rearranged, reordered, omitted, and/or otherwise modified such that other implementations are possible and contemplated.

At 705, method 700 may include applying a deep negative bias based on activating a wordline. For example, method 700 may include a wordline circuit configured to determine a wordline of the wordline circuit is activated and applying a deep negative bias (e.g., a negative bias voltage that is lower than a default negative bias voltage) to one or more wordlines of the wordline circuit (e.g. including the wordline that is activated).

At 710, method 700 may include applying a default negative bias based on deactivating the wordline. For example, based on the wordline circuit determining the wordline is deactivated, the wordline circuit may switch from the deep negative bias to the default negative bias (e.g., switch back to the default negative bias).

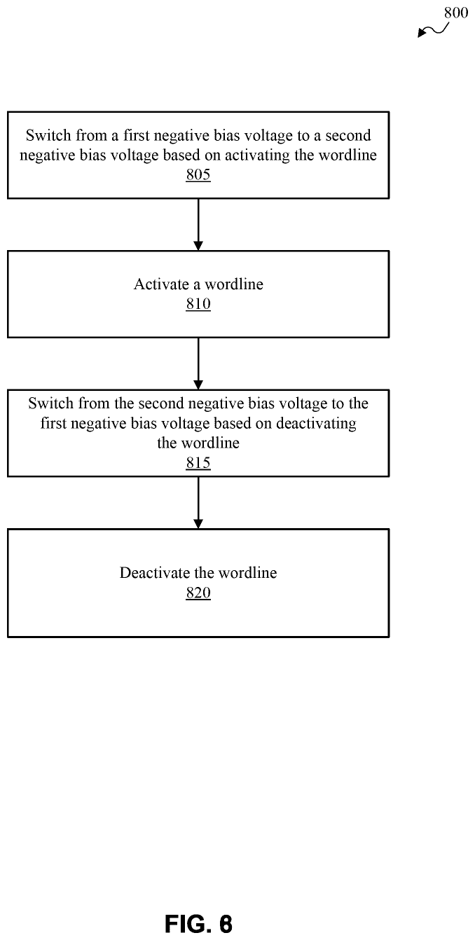

FIG. 8 depicts a flow diagram illustrating an example method 800 associated with the disclosed systems, in accordance with example implementations described herein. In some configurations, one or more aspects of method 800 may be implemented by or in conjunction with machine 105, components of machine 105, or any combination thereof. The depicted method 800 is just one implementation and one or more operations of method 800 may be rearranged, reordered, omitted, and/or otherwise modified such that other implementations are possible and contemplated.

At 805, method 800 may include switching from a first negative bias voltage to a second negative bias voltage based on a wordline being activated. For example, the wordline circuit may switch from a first negative bias voltage (e.g., a default negative bias voltage) to a second negative bias voltage (e.g., a deep negative bias voltage) based on the wordline circuit determining a wordline is selected for activation. It is noted that the bias voltage may be switched for a portion of a memory device. For example, the bias voltage may be switched (e.g., to deep negative bias voltage) for a MAT or wordline stack of a memory device that includes the activated wordline. A MAT or wordline stack of the memory device that does not include the activated wordline may remain at the default negative bias voltage.

At 810, method 800 may include activating the wordline. For example, a wordline circuit may activate a wordline of a target MAT or wordline stack.

At 815, method 800 may include switching from the second negative bias voltage to the first negative bias voltage based on deactivating the wordline or based on an impending deactivation of the wordline. For example, the wordline circuit may switch from the second negative bias voltage to the first negative bias voltage (e.g., back to the first negative bias voltage) based on the wordline circuit determining that the wordline is deactivated or that the wordline is going to be deactivated.

At 820, method 800 may include deactivating the wordline. For example, the wordline circuit may deactivate the wordline of a target MAT or wordline stack.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wired and/or wireless communication device such as a switch, router, network interface controller, cellular telephone, smartphone, tablet, netbook, wireless terminal, laptop computer, a femtocell, High Data Rate (HDR) subscriber station, access point, printer, point of sale device, access terminal, or other personal communication system (PCS) device. The device may be wireless, wired, mobile, and/or stationary.

As used within this document, the term “communicate” is intended to include transmitting, or receiving, or both transmitting and receiving. Similarly, the bidirectional exchange of data between two devices (both devices transmit and receive during the exchange) may be described as ‘communicating’, when only the functionality of one of those devices is being claimed. The term “communicating” as used herein with respect to wired and/or wireless communication signals includes transmitting the wired and/or wireless communication signals and/or receiving the wired and/or wireless communication signals. For example, a communication unit, which is capable of communicating wired and/or wireless communication signals, may include a wired/wireless transmitter to transmit communication signals to at least one other communication unit, and/or a wired/wireless communication receiver to receive the communication signal from at least one other communication unit.

Some embodiments may be used in conjunction with various devices and systems, for example, a Personal Computer (PC), a desktop computer, a mobile computer, a laptop computer, a notebook computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless Access Point (AP), a wired or wireless router, a wired or wireless modem, a video device, an audio device, an audio-video (A/V) device, a wired or wireless network, a wireless area network, a Wireless Video Area Network (WVAN), a Local Area Network (LAN), a Wireless LAN (WLAN), a Personal Area Network (PAN), a Wireless PAN (WPAN), and the like.

Some embodiments may be used in conjunction with one way and/or two-way radio communication systems, cellular radio-telephone communication systems, a mobile phone, a cellular telephone, a wireless telephone, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, Digital Video Broadcast (DVB) devices or systems, multi-standard radio devices or systems, a wired or wireless handheld device, e.g., a Smartphone, a Wireless Application Protocol (WAP) device, or the like.

Some embodiments may be used in conjunction with one or more types of wireless communication signals and/or systems following one or more wireless communication protocols, for example, Radio Frequency (RF), Infrared (IR), Frequency-Division Multiplexing (FDM), Orthogonal FDM (OFDM), Time-Division Multiplexing (TDM), Time-Division Multiple Access (TDMA), Extended TDMA (E-TDMA), General Packet Radio Service (GPRS), extended GPRS, Code-Division Multiple Access (CDMA), Wideband CDMA (WCDMA), CDMA 2000, single-carrier CDMA, multi-carrier CDMA, Multi-Carrier Modulation (MDM), Discrete Multi-Tone (DMT), Bluetooth™, Global Positioning System (GPS), Wi-Fi, Wi-Max, ZigBee™, Ultra-Wideband (UWB), Global System for Mobile communication (GSM), 2G, 2.5G, 3G, 3.5G, 4G, Fifth Generation (5G) mobile networks, 3GPP, Long Term Evolution (LTE), LTE advanced, Enhanced Data rates for GSM Evolution (EDGE), or the like. Other embodiments may be used in various other devices, systems, and/or networks.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, e.g., one or more components of computer program instructions, encoded on computer storage medium for execution by, or to control the operation of, information/data processing apparatus. Alternatively, or in addition, the program instructions can be encoded on an artificially-generated propagated signal, for example, a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (for example multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, for example, an FPGA or an ASIC. The apparatus can also include, in addition to hardware, code that creates an execution environment for the computer program in question, for example code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random-access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, for example, a CRT (cathode ray tube) or LCD (liquid crystal display) monitor, for displaying information/data to the user and a keyboard and a pointing device, for example, a mouse or a trackball, by which the user can provide input to the computer. Other kinds of devices can be used to provide for interaction with a user as well; for example, feedback provided to the user can be any form of sensory feedback, for example visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, for example, as an information/data server, or that includes a middleware component, for example, an application server, or that includes a front-end component, for example, a client computer having a graphical user interface or a web browser through which a user can interact with an embodiment of the subject matter described herein, or any combination of one or more such back-end, middleware, or front-end components. The components of the system can be interconnected by any form or medium of digital information/data communication, for example, a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example, an HTML page) to a client device (for example, for purposes of displaying information/data to and receiving user input from a user interacting with the client device). Information/data generated at the client device (for example, a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples as set forth herein will come to mind to one skilled in the art to which these embodiments pertain to having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A wordline circuit comprising:
a first transistor connected to a first negative bias voltage and a first wordline enable signal;
a second transistor connected to a second negative bias voltage and a second wordline enable signal; and
a third transistor connected to the first transistor, the second transistor, a first wordline driving signal, and a wordline of the wordline circuit.

2. The wordline circuit of claim 1, wherein:
a drain terminal of the second transistor connects to a source terminal of the third transistor,
a gate terminal of the second transistor connects to the second wordline enable signal, and
a source terminal of the second transistor connects to the second negative bias voltage.

3. The wordline circuit of claim 2, wherein:
a drain terminal of the first transistor connects to the source terminal of the third transistor,
a gate terminal of the first transistor connects to the first wordline enable signal, and
a source terminal of the first transistor connects to the first negative bias voltage.

4. The wordline circuit of claim 1, wherein:
a drain terminal of the third transistor connects to the wordline, and
a gate terminal of the third transistor connects to the first wordline driving signal.

5. The wordline circuit of claim 1, further comprising a fourth transistor, wherein:
a drain terminal of the fourth transistor connects to a second wordline driving signal,
a gate terminal of the fourth transistor connects to the first wordline enable signal, and
a source terminal of the fourth transistor connects to the wordline.

6. The wordline circuit of claim 5, wherein the second wordline driving signal is a complement of the first wordline driving signal.

7. The wordline circuit of claim 5, further comprising a fifth transistor, wherein:
a drain terminal of the fifth transistor connects to the wordline and to the source terminal of the fourth transistor,
a gate terminal of the fifth transistor connects to the first wordline enable signal and the gate terminal of the fourth transistor, and
the source terminal of the fifth transistor connects to the second transistor, the first transistor, and the third transistor.

8. The wordline circuit of claim 1, wherein:
the second negative bias voltage is a lower voltage than the first negative bias voltage, and
the first wordline enable signal is a complement of the second wordline enable signal.

9. A method comprising:
applying a first negative bias voltage to a wordline circuit of a stacked memory module, the wordline circuit being associated with a first set of wordlines of the stacked memory module;
applying a second negative bias voltage to the wordline circuit instead of the first negative bias voltage based on a wordline being selected for activation;
activating the wordline of the first set of wordlines;
re-applying the first negative bias voltage to the wordline circuit based on the wordline being selected for deactivation; and
deactivating the wordline of the first set of wordlines.

10. The method of claim 9, wherein determining the wordline is selected for activation is based on raising an activation signal of the wordline from a first voltage level to a second voltage level that is higher than the first voltage level.

11. The method of claim 10, wherein determining the wordline is deactivated is based on lowering the activation signal from the second voltage level to the first voltage level.

12. The method of claim 10, wherein the activation signal comprises a partial no write signal of the wordline.

13. The method of claim 9, wherein the stacked memory module comprises multiple wordline circuits that include at least the wordline circuit and a second wordline circuit.

14. The method of claim 13, wherein the second wordline circuit is associated with a second set of wordlines different from the first set of wordlines, the first negative bias voltage being applied to the second set of wordlines concurrent with the second negative bias voltage being applied to the first set of wordlines.

15. A stacked memory module comprising multiple wordline circuits, a wordline circuit of the multiple wordline circuits comprising:
a first transistor connected to a first negative bias voltage and a first wordline enable signal;
a second transistor connected to a second negative bias voltage and a second wordline enable signal; and
a third transistor connects to the first transistor, the second transistor, a first wordline driving signal, and a wordline of the wordline circuit.

16. The stacked memory module of claim 15, wherein:
a drain terminal of the second transistor connects to a source terminal of the third transistor,
a gate terminal of the second transistor connects to the second wordline enable signal, and
a source terminal of the second transistor connects to the second negative bias voltage.

17. The stacked memory module of claim 16, wherein:
a drain terminal of the first transistor connects to the source terminal of the third transistor,
a gate terminal of the first transistor connects to the first wordline enable signal, and
a source terminal of the first transistor connects to the first negative bias voltage.

18. The stacked memory module of claim 15, wherein:
a drain terminal of the third transistor connects to the wordline, and
a gate terminal of the third transistor connects to the first wordline driving signal.

19. The stacked memory module of claim 15, the wordline circuit further comprising a fourth transistor, wherein:
a drain terminal of the fourth transistor connects to a second wordline driving signal,
a gate terminal of the fourth transistor connects to the first wordline enable signal, and
a source terminal of the fourth transistor connects to the wordline.

20. The stacked memory module of claim 19, the wordline circuit further comprising a fifth transistor, wherein:
a drain terminal of the fifth transistor connects to the wordline and to the source terminal of the fourth transistor,
a gate terminal of the fifth transistor connects to the first wordline enable signal and the gate terminal of the fourth transistor, and
the source terminal of the fifth transistor connects to the second transistor, the first transistor, and the third transistor.
